(19) United States
(12) Patent Application Publication
(10) Pub. No.: US 2023/0341776 A1
(43) Pub. Date: Oct. 26, 2023

(54) RESIST COMPOUND AND METHOD OF FORMING PATTERN USING THE SAME

(71) Applicant: SAMSUNG ELECTRONICS CO., LTD., Suwon-si (KR)

(72) Inventors: HOYOUNG KIM, Suwon-si (KR); Youngkwan LEE, Suwon-si (KR); SOOCHAN KIM, Suwon-si (KR); Hyungjun CHEE, Suwon-si (KR); HYUNWOO KIM, Suwon-si (KR); SONGSE YI, Suwon-si (KR)

(73) Assignees: SAMSUNG ELECTRONICS CO., LTD., Suwon-si (KR); RESEARCH & BUSINESS FOUNDATION SUNGKYUNKWAN UNIVERSITY, Suwon-si (KR)

(21) Appl. No.: 18/106,254

(22) Filed: Feb. 6, 2023

(30) Foreign Application Priority Data
Apr. 26, 2022 (KR) 10-2022-0051653

(51) Int. Cl. G03F 7/06; C07F 1/00

(52) U.S. Cl. CPC G03F 7/06; C07F 1/005

(57) ABSTRACT

A resist compound is represented by Formula 1:

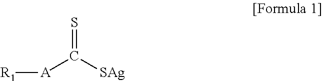

wherein R₁ is an alkyl group having 1 to 12 carbon atoms, an alkenyl group having 1 to 12 carbon atoms, or a hydrocarbon ring group having 3 to 12 carbon atoms, and A bonded to R₁ is O or NR₂, wherein R₂ is hydrogen, an alkyl group having 1 to 12 carbon atoms, an alkenyl group having 1 to 12 carbon atoms, or a hydrocarbon ring group having 3 to 12 carbon atoms. A resist composition includes the resist compound and an organic solvent. A method for forming a resist pattern includes forming a resist layer by applying the resist composition including the resist compound on a substrate, irradiating light onto the resist layer to provide an irradiated resist layer, and developing the irradiated resist layer to form a resist pattern.

### CROSS-REFERENCE TO RELATED APPLICATIONS

This application claims priority to Korean Patent Application No. 10-2022-0051653, filed on Apr. 26, 2022, in the Korean Intellectual Property Office, the entire contents of which are hereby incorporated by reference.

### BACKGROUND OF THE INVENTION

The present disclosure relates to a resist compound, and more particularly, relates to a resist compound used for manufacturing a semiconductor device.

Photolithography may include irradiating light of a certain wavelength to a resist layer to cause a change in a chemical structure of the resist layer and selectively removing an exposed portion or an unexposed portion by using a difference in solubility between the exposed and unexposed portion of the resist layer. Recently, as a semiconductor device has become highly integrated and miniaturized, it is required that components of the semiconductor device have fine pitch and width. As a result, the importance of a resist compound for forming a fine pattern is increasing.

### SUMMARY

An embodiment provides a resist compound having high photosensitivity characteristics and high reactivity.

An embodiment provides a method for forming a fine and uniform pattern and a resist compound used therein.

According to an embodiment, a resist compound is represented by Formula 1.

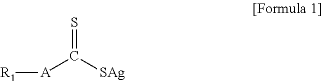

In Formula 1, “R₁” is an alkyl group having 1 to 12 carbon atoms, an alkenyl group having 1 to 12 carbon atoms, or a hydrocarbon ring group having 3 to 12 carbon atoms, and “A” bonded to “R₁” is O or NR₂, wherein “R₂” is hydrogen, an alkyl group having 1 to 12 carbon atoms, an alkenyl group having 1 to 12 carbon atoms, or a hydrocarbon ring group having 3 to 12 carbon atoms.

According to an embodiment, a resist composition includes a resist compound represented by Formula 1 and an organic solvent.

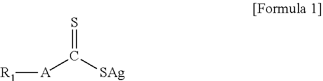

In Formula 1, “R₁” is an alkyl group having 1 to 12 carbon atoms, an alkenyl group having 1 to 12 carbon atoms, or a hydrocarbon ring group having 3 to 12 carbon atoms, and “A” bonded to “R₁” is O or NR₂, wherein “R₂” is hydrogen, an alkyl group having 1 to 12 carbon atoms, an alkenyl group having 1 to 12 carbon atoms, or a hydrocarbon ring group having 3 to 12 carbon atoms.

According to an embodiment, a method of forming a pattern includes forming a resist layer by applying a resist composition including the resist compound on a substrate, performing an exposure process of irradiating light onto the resist layer, and performing a developing process on the resist layer to form a resist pattern.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a plan view illustrating a resist pattern according to embodiments.

FIGS. 2 to 5 are views for explaining the formation of a lower pattern according to embodiments.

FIGS. 6 to 8 are views for explaining the formation of another lower pattern according to embodiments.

FIG. 9 is a graph illustrating the result of thermogravimetric analysis of a resist compound of Experimental Example 1.

FIG. 10 is a graph illustrating the result of evaluating photosensitivity characteristics of a resist layer of Experimental Example 2 to EUV.

FIG. 11A is a graph illustrating the result of a Fourier-transform infrared spectroscopy (FT-IR) analysis of a resist layer of Experimental Example 1 before an exposure process.

FIG. 11B is a graph illustrating the result of a Fourier transform infrared spectroscopic analysis of an exposed resist layer of Experimental Example 1 after an EUV exposure process.

FIG. 12 is a graph illustrating the result of an X-ray diffraction (hereinafter, XRD) analysis of an EUV-exposed resist layer of Experimental Example 1.

### DETAILED DESCRIPTION

As used herein, an alkyl group may be a linear alkyl group, a branched alkyl group, or a cyclic alkyl group. The number of carbon atoms in the alkyl group is not particularly limited, but may be an alkyl group having 1 to 12 carbon atoms. Examples of the alkyl group include a methyl group, an ethyl group, an n-propyl group, an isopropyl group, an n-butyl group, a t-butyl group, an i-butyl group, a 2-ethylbutyl group, a 3,3-dimethylbutyl group, an n-pentyl group, an i-pentyl group, a neopentyl group, a t-pentyl group, a cyclopentyl group, and the like, but are not limited thereto.

As used herein, an alkenyl group may be a linear alkenyl group or a branched alkenyl group. The number of carbon atoms in the alkenyl group is not particularly limited, but may be 1 or more and 12 or less. Examples of the alkenyl group include a 1-butenyl group, a 1-pentenyl group, and a 1,3-butadienyl group, a vinyl group, and the like, but are not limited thereto.

As used herein, the alkenyl group may include an allyl group.

As used herein, a hydrocarbon ring includes an aliphatic hydrocarbon ring and an aromatic hydrocarbon ring. The hydrocarbon ring may be monocyclic or polycyclic. The number of carbon atoms in the aromatic hydrocarbon ring is not particularly limited, but may have 3 to 12 carbon atoms. As used herein, the aromatic ring may include an aromatic hydrocarbon ring. The aromatic hydrocarbon ring may be an aryl group.

In the present specification, examples of halogen include, but are not limited to, fluorine (F), chlorine (Cl), bromine (Br), and iodine (I).

Unless otherwise defined in a chemical formula of the present specification, when a chemical bond is not drawn at a position where a chemical bond may be drawn, it can mean that a hydrogen atom is bonded to the position.

As used herein, the like elements are designated with the same reference numerals over the present specification.

Hereinafter, a resist compound and a resist composition including the same according to embodiments will be described.

According to an embodiment, a resist composition may be used for forming a pattern or for manufacturing a semiconductor device. For example, the resist composition may be used in a patterning process for manufacturing a semiconductor device. The resist composition includes a resist compound. The resist compound may be an extreme ultraviolet (EUV) resist compound or an electron beam (e-beam) resist compound. Extreme ultraviolet may refer to ultraviolet radiation having a wavelength of 10 nm to 124 nm, specifically, a wavelength of 13.0 nm to 13.9 nm, and more specifically, a wavelength of 13.4 nm to 13.6 nm. The resist compound may be a metal chalcogen compound. In some embodiments, the resist compound may be represented by Formula 1 below.

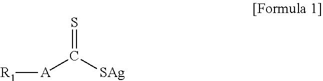

In Formula 1, “R₁” is an alkyl group having 1 to 12 carbon atoms, an alkenyl group having 1 to 12 carbon atoms, or a hydrocarbon ring group having 3 to 12 carbon atoms, and “A” bonded to “R₁” is O or NR₂, wherein “R₂” is hydrogen, an alkyl group having 1 to 12 carbon atoms, an alkenyl group having 1 to 12 carbon atoms, or a hydrocarbon ring group having 3 to 12 carbon atoms.

For example, in Formula 1, “R₁” may be an alkyl group having 1 to 12 carbon atoms. Specifically, “R₁” may be an alkyl group having 1 to 5 carbon atoms. “R₁” of Formula 1 may be a methyl group, an ethyl group, a propyl group, a butyl group, or a pentyl group, but is not limited thereto. When the number of carbon atoms in “R₁” is excessively large (e.g., 13 or more), reactivity of the resist compound to extreme ultraviolet may decrease.

For example, a compound represented by Formula 1 may be Ag—O-alkyl dithiocarbonate or Ag—N-alkyl dithiocarbonate, but is not limited thereto.

The compound represented by Formula 1 may be represented by Formula 2 or Formula 3 below.

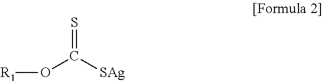

In Formula 2, “R₁” is an alkyl group having 1 to 12 carbon atoms, an alkenyl group having 1 to 12 carbon atoms, or a hydrocarbon ring group having 3 to 12 carbon atoms.

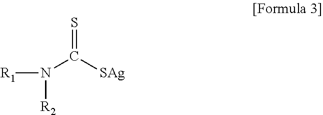

In Formula 3, “R₁” is an alkyl group having 1 to 12 carbon atoms, an alkenyl group having 1 to 12 carbon atoms, or a hydrocarbon ring group having 3 to 12 carbon atoms, and “R₂” is hydrogen, an alkyl group having 1 to 12 carbon atoms, an alkenyl group having 1 to 12 carbon atoms, or a hydrocarbon ring group having 3 to 12 carbon atoms.

According to embodiments, a compound represented by Formula 1 includes silver (Ag). Silver (Ag) may be well combined with an alkyl dithiocarbonate. The alkyl dithiocarbonate may be O-alkyl dithiocarbonate or N-alkyl dithiocarbonate. For example, silver (Ag) may be bonded with an alkyl dithiocarbonate. The bonding may include, but is not limited to, a chemical bond such as a covalent bond. The compound represented by Formula 1 included silver (Ag), and thus the resist compound according to embodiments may well form a resist layer by a coating process.

The resist compound according to embodiments may have high absorbance with respect to light. The resist compound may be reactive to light. For example, a reaction of the resist compound by light irradiation may be represented by Reaction Formula 1 below. The light may be extreme ultraviolet (EUV) or an electron beam (e-beam) as described above.

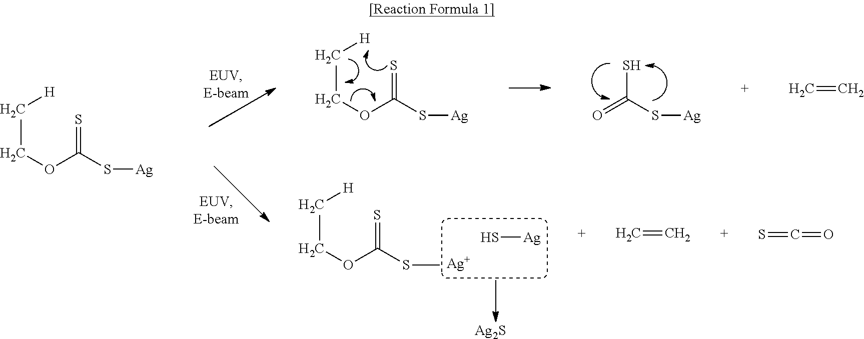

The resist compound according to embodiments may be mixed with a solvent to prepare a resist composition. In this case, the solvent may be an organic solvent. The organic solvent may include an alcohol solvent, a nitrile solvent, an acetate solvent, a halogenated alkyl solvent, an aromatic ether solvent, an amide solvent, or mixtures thereof. The alcohol solvent may include ethanol. The nitrile solvent may include acetonitrile. The acetate solvent may include, for example, propylene glycol methyl ether acetate. The halogenated alkyl solvent may include chloroform. The aromatic ether solvent may include an anisole solvent. The amide solvent may include dimethylformamide.

The resist composition according to embodiments may not include a photoacid generator.

A resist layer may be formed using the resist composition according to embodiments.

Hereinafter, a method of manufacturing a resist compound according to embodiments will be described.

Preparation of the resist compound represented by Formula 2 may proceed as shown in Reaction Formula 2 below.

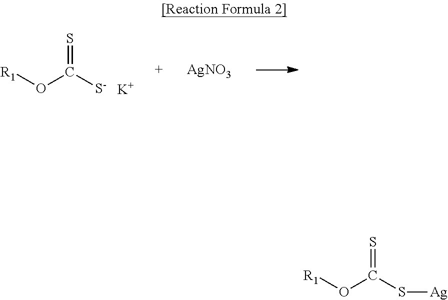

In Reaction Formula 2, “R₁” is as defined in Formula 2.

The preparation of the resist compound represented by Formula 3 may proceed as shown in Reaction Formula 3 below.

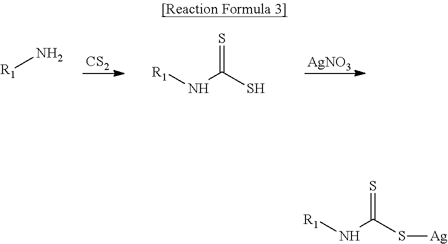

In Reaction Formula 3, “R₁” is as defined in Formula 3.

Hereinafter, a method for preparing a resist compound and a pattern forming method using the same according to embodiments will be described.

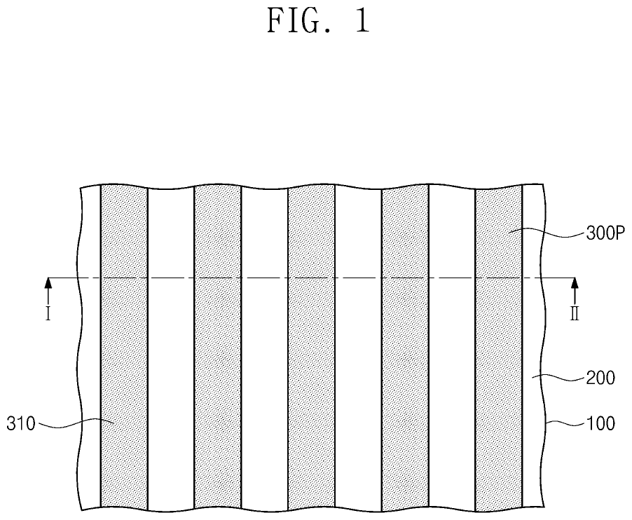

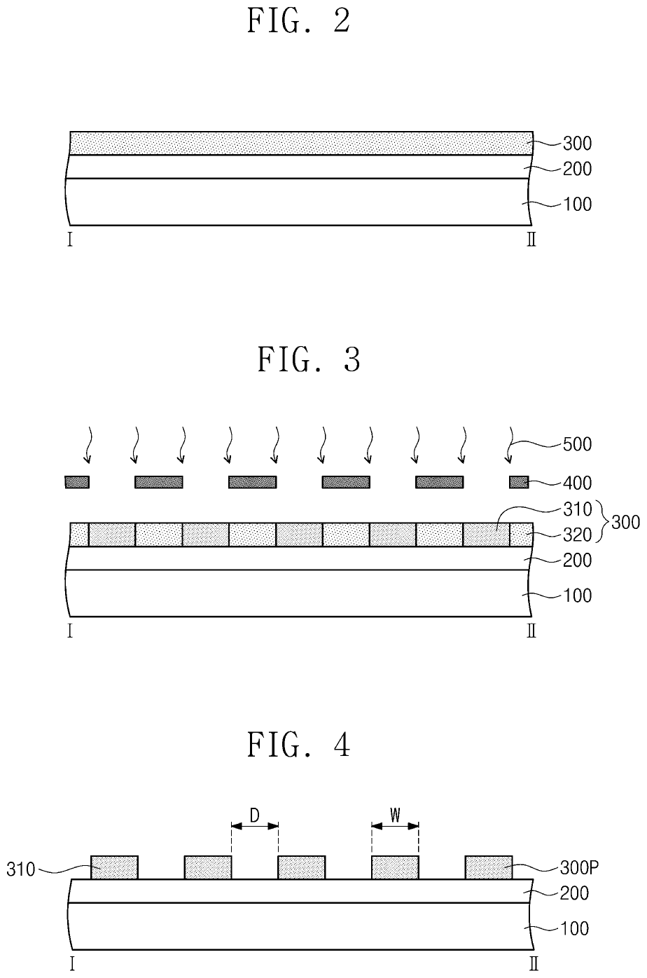

FIG. 1 is a plan view illustrating a resist pattern according to embodiments. FIGS. 2 to 5 are views for explaining the formation of a lower pattern according to embodiments and correspond to cross-sectional views taken along line I-II of FIG. 1.

Referring to FIGS. 1 and 2, a substrate 100 may be prepared. A lower layer 200 and a resist layer 300 may be sequentially formed on the substrate 100. The lower layer 200 may be an etch target layer. The lower layer 200 may be formed of any one selected from a semiconductor material, a conductive material, and an insulating material or a combination thereof. In addition, the lower layer 200 may be formed as a single layer or may be a plurality of stacked layers. Although not shown, additional layers may be provided between the substrate 100 and the lower layer 200.

A resist composition according to embodiments may be prepared. The resist composition may include a resist compound represented by Formula 1 and an organic solvent. The resist composition may be applied on the lower layer 200 to form the resist layer 300. The resist composition may be applied by spin coating.

A pre-bake process may be further performed on the resist layer 300. The pre-bake process may include heat-treating the resist layer 300 under a first temperature condition. The first temperature may be 80° C. to 150° C. The resist compound according to embodiments may have thermal stability under the first temperature condition. Accordingly, damage or deformation of the resist layer 300 in the pre-bake process may be prevented.

Referring to FIGS. 1 and 3, the resist layer 300 may be exposed by a light 500. The light 500 may be an electron beam or extreme ultraviolet. Before the light 500 is irradiated, a photomask 400 may be disposed on the resist layer 300. The light 500 may be irradiated onto a first portion 310 of the resist layer 300 exposed by the photomask 400. When the resist layer 300 is exposed to the light 500, a chemical structure of the resist compound may be changed. For example, reaction of the resist compound represented by Formula 1 may be generated by the light 500. For example, the reaction of the resist compound by the light 500 may proceed as in Reaction Formula 1 above.

A second portion 320 of the resist layer 300 may not be exposed to the light 500. A chemical structure of the resist compound in the second portion 320 of the resist layer 300 may not be changed. Accordingly, after irradiation of the light 500 is completed, the first portion 310 of the resist layer 300 may have a different chemical structure from that of the second portion 320.

The resist compound according to embodiments may have high absorbance and high reactivity with respect to the light 500, and thus the first portion 310 of the resist layer 300 may be formed at a desired position. Undesirable errors in the exposure process may be prevented.

According to embodiments, the resist compound includes silver (Ag), and may be a non-chemically amplified resist (non-CAR) compound. For example, the structure of the first portion 310 of the resist layer 300 may be directly changed by the light. The resist layer 300 may not include a separate photoacid generator. Accordingly, a shape of the first portion 310 of the resist layer 300 or a resist pattern 300P to be described later in FIG. 4 may be prevented from being deformed by the photoacid generator.

In some embodiments, a post-exposure bake (PEB) may be further performed on the resist layer 300. The post-exposure bake process may include heat treatment at a second temperature condition. The second temperature may be higher than the first temperature. For example, the second temperature may be 150° C. to 250° C. The resist compounds according to embodiments may have thermal stability under the second temperature condition. Accordingly, during the post-exposure bake process, the shape of each of the first portion 310 and the second portion 320 of the resist layer 300 may not be deformed.

Thereafter, the photomask 400 may be removed.

Referring to FIGS. 1 and 4, a developing process using a developer may be performed on the resist layer 300 to form a resist pattern 300P. The developing process may include providing a developer on the resist layer 300. The second portion 320 of the resist layer 300 may have high reactivity to the developer. As a result of the developing process, the second portion 320 of the resist layer 300 may be removed by the developer. The developer may have low reactivity with respect to the first portion 310 of the resist layer 300. The first portion 310 of the resist layer 300 may remain without being removed to form the resist pattern 300P. The resist pattern 300P may be a negative tone pattern.

The resist compound according to embodiments has high absorbance and high reactivity with respect to the light (500 in FIG. 3), and the resist pattern 300P may have a uniform line-edge roughness (LER) characteristics and improved line width roughness (LWR) characteristics. When the exposure process is performed using extreme ultraviolet, the resist pattern 300P may be formed with a finer width “W and distance “D”.

As described in FIG. 1, the resist pattern 300P may have a linear planar shape. For example, the resist pattern 300P may include portions extending in one direction. However, a planar shape of the resist pattern 300P may be variously modified, such as a zigzag shape, a honeycomb shape, or a circular shape. The resist pattern 300P may expose the lower layer 200.

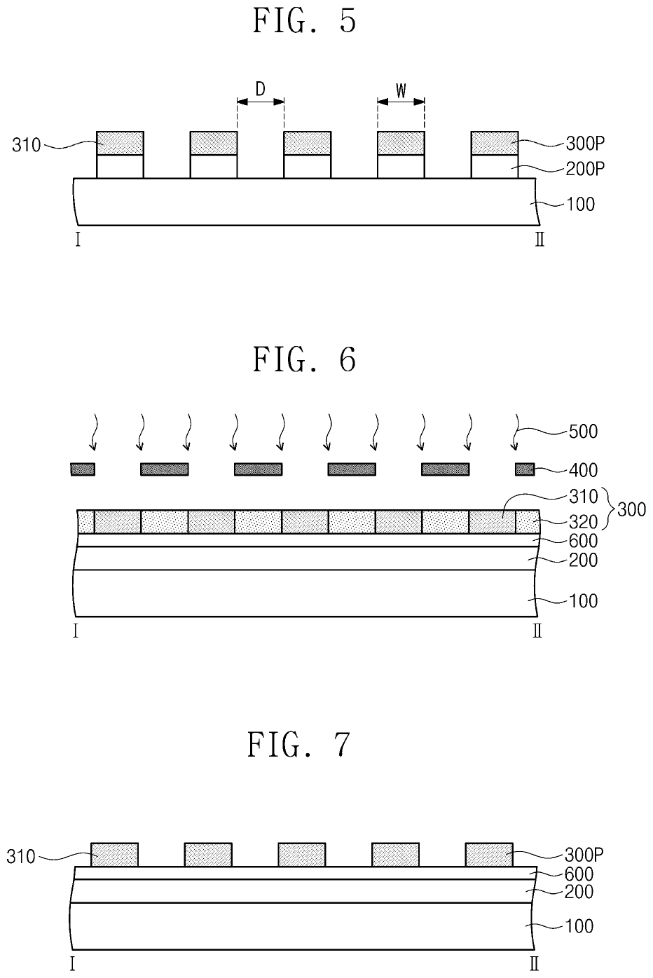

Referring to FIGS. 1 and 5, the lower layer 200 may be etched to form a lower pattern 200P. The lower layer 200 may have etch selectivity with respect to the resist pattern 300P. The lower pattern 200P may expose the substrate 100. As another example, the lower pattern 200P may expose another layer interposed between the substrate 100 and the lower pattern 200P. Thereafter, the resist pattern 300P may be removed. Accordingly, a formation of the pattern may be completed. The pattern may refer to the lower pattern 200P. A width of the lower pattern 200P may correspond to the width “W” of the resist pattern 300P. The resist pattern 300P may have a narrow width “W”, and thus the lower pattern 200P may be formed with a narrow width. A distance between pattern portions of the lower pattern 200P may correspond to the distance “D” between the pattern portions of the resist pattern 300P.

According to embodiments, the lower pattern 200P may be a component of a semiconductor device. For example, the lower pattern 200P may be a semiconductor pattern, a conductive pattern, or an insulating pattern in the semiconductor device.

FIGS. 6 to 8 are views for explaining a formation of a lower pattern according to embodiments, and correspond to cross-sectional views taken along line I-II of FIG. 1.

Referring to FIG. 6, a resist layer 300 and a lower layer 200 may be formed on a substrate 100. The substrate 100, the lower layer 200, and the resist layer 300 may be substantially the same as described above with reference to FIG. 2. However, a resist under-layer 600 may be further formed between the lower layer 200 and the resist layer 300. The resist under-layer 600 may include an organic material or an inorganic material. An exposure process may be performed on the resist layer 300. The exposure process may be substantially the same as described with reference to FIG. 3. For example, a chemical structure of the resist compound included in a first portion 310 of the resist layer 300 may be deformed by a light 500. The resist under-layer 600 may be provided, and thus the chemical structure of the first portion 310 of the resist layer 300 may be more easily deformed. After the exposure process is completed, the first portion 310 of the resist layer 300 may have a different chemical structure from that of the second portion 320.

Referring to FIG. 7, a developing process may be performed on the resist layer 300. The second portion 320 of the resist layer 300 may be removed by a developer to form a resist pattern 300P. The first portion 310 of the resist layer 300 may not be removed by the developer. The resist pattern 300P may correspond to the first portion 310 of the resist layer 300. The resist pattern 300P may expose the resist under-layer 600.

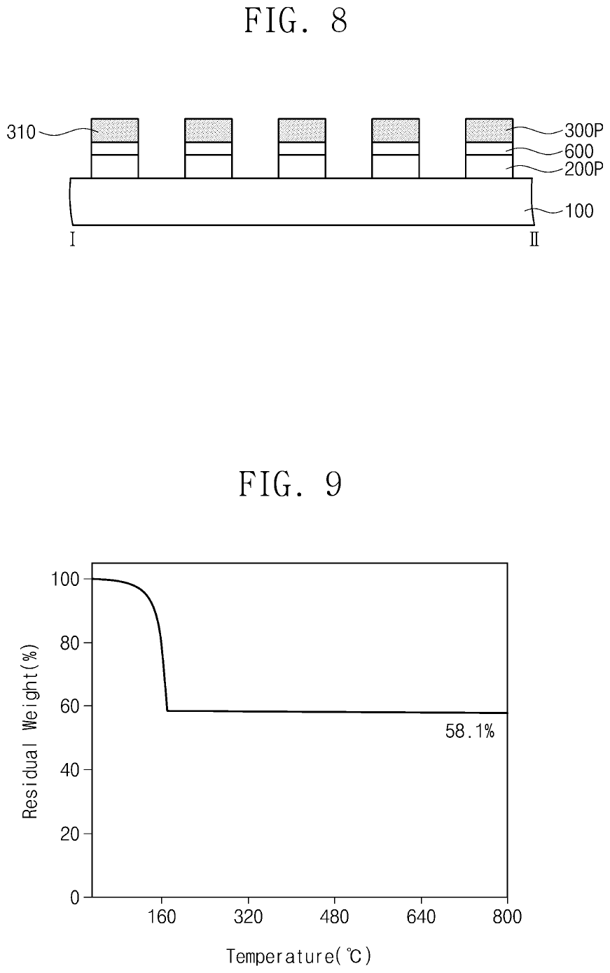

Referring to FIG. 8, the exposed resist under-layer 600 and the lower layer 200 may be etched to form a lower pattern 200P. The etching of the lower layer 200 may be substantially the same as the method described with reference to FIG. 5. Thereafter, the resist under-layer 600 and the resist pattern 300P may be removed.

Hereinafter, with reference to the Experimental Examples of embodiments, preparation of a resist composition and a formation of a resist pattern will be described.

### 1. Preparation of Resist Composition and Formation of Resist Layer

### Experimental Examples 1 to 4

Deionized water (DI water) was added to and mixed with a starting material of Table 1 and silver nitrate in a molar ratio of 1:1 to prepare a resist compound. The starting material was potassium O-alkyl dithiocarbonate. The resist compound was added to an organic solvent to prepare a resist composition.

A resist layer was formed by coating the resist composition on a silicon substrate. In this case, a Si₃N₄ wafer having a size of 2 cm×2 cm was used as a silicon substrate.

### Experimental Example 5

0.05 mol of Ag₂O was mixed in a solution of CS₂ and 1-buytlamine having a molar ratio of 1:1 in chloroform to carry out a reaction shown in Reaction Formula 3A below.

A resist layer was formed on a silicon substrate in the same manner as in Experimental Example 1, except that the resist composition of Experimental Example 5 was used.

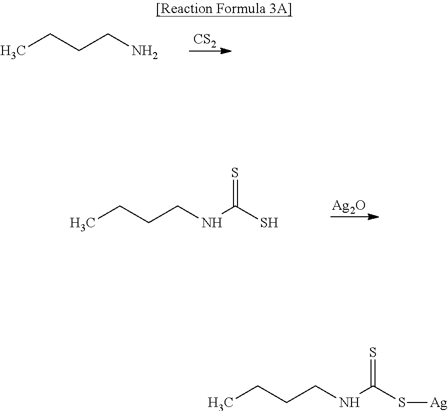

### Comparative Example 1

Ethanol 4 ml, methacrylic acid 4 ml, and HCl 1.8 ml (0.37M) were mixed and stirred, and then silver methacrylate powder (0.45M) and ethanolamine 0.27 ml were mixed therein to prepare a resist composition of Comparative Example 1.

A resist layer was formed on a silicon substrate in the same manner as in Experimental Example 1, except that the resist composition of Comparative Example 1 was used.

### Comparative Example 2

Silver trifluoroacetate was prepared from trifluoroacetate. Silver trifluoroacetate was dissolved in dimethylformamide (hereinafter, DMF) to prepare a resist composition of Comparative Example 2.

A resist layer was formed on a silicon substrate in the same manner as in Experimental Example 1, except that the resist composition of Comparative Example 2 was used.

Table 1 shows starting materials used in the preparation of the resist compounds of Experimental Examples 1 to 5, Comparative Example 1, and Comparative Example 2.

TABLE 1

| | Starting material |
|---|---|
| Experimental Example 1 | 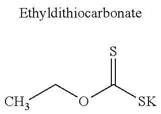 |
| Experimental Example 2 | 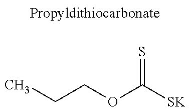 |
| Experimental Example 3 | 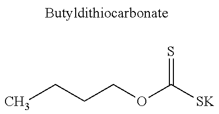 |
| Experimental Example 4 | 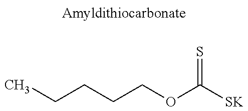 |
| Experimental Example 5 | 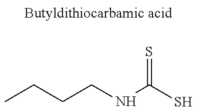 |
| Comparative Example 1 | 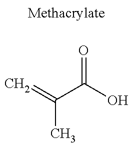 |
| Comparative Example 2 | 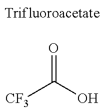 |

### 2. Evaluation of Resist Composition and Resist Layer

Table 2 shows resist layer coating evaluation results and EUV reactivity evaluation results of Experimental Examples and Comparative Examples.

TABLE 2

| | Starting material | Resist layer coating evaluation | EUV reactivity |
|---|---|---|---|
| Experimental Example 1 | 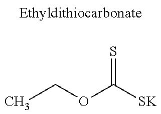 | ◯ | ◯ |
| Experimental Example 2 | 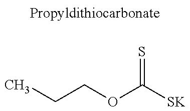 | ◯ | ◯ |
| Experimental Example 3 | 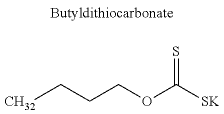 | ◯ | — |
| Comparative Example 1 | 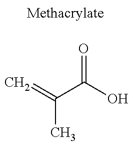 | ◯ | X |
| Comparative Example 2 | 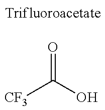 | X | # |

Resist layer coating evaluation
◯: good
X: poor
EUV reactivity evaluation
◯: reactive
X: non-reactive
—: no evaluation
#: impossible to evaluate IUV reactivity due to poor resist layer

Referring to Table 2, the resist layers prepared using the resist compositions of Experimental Example 1, Experimental Example 2, and Experimental Example 3 were evaluated to be well coated. The resist compositions of Experimental Examples 1 and 2 were reactive to EUV. In the case of Comparative Example 1, the resist layer was non-reactive to EUV. When the resist composition of Comparative Example 2 was used, the coating characteristics of the resist layer were poor. In the case of Comparative Example 2, the resist layer was poor, and thus EUV characteristics of the resist layer could not be evaluated.

Table 3 shows the results of measuring particle sizes of the resist compositions of the Experimental Examples and Comparative Examples.

TABLE 3

| | average particle size (nm) |
|---|---|
| Experimental Example 1 | 5.10 |
| Experimental Example 2 | 5.40 |
| Experimental Example 3 | 5.83 |
| Experimental Example 4 | 6.36 |
| Experimental Example 5 | 7.45 |
| Comparative Example 1 | 5.46 |
| Comparative Example 2 | 5.31 |

Referring to Table 3, the resist compositions of Experimental Example 1, Experimental Example 2, Experimental Example 3, Experimental Example 4, and Experimental Example 5 were evaluated to have relatively small particle sizes.

When the particle size of the resist compositions is reduced, the resist layer prepared using the resist composition may be finely patterned. The resist pattern including the resist compositions may have improved line width roughness (LWR) characteristics.

FIG. 9 is a graph illustrating the result of thermogravimetric analysis of a resist compound of Experimental Example 1. The x-axis shows temperature, and the y-axis shows a residual weight of the resist compound.

Referring to FIG. 9, the weight of a resist compound partially decreased around 160° C., and remained relatively constant at a temperature of 160° C. to 800° C. It may be seen that the resist compound has thermal stability at a temperature of 160° C. to 800° C.

The resist layer manufactured using the resist compound according to embodiments may have thermal stability, and thus may not be deformed in a pre-bake process and a post-exposure baking process.

Table 4 shows the results of measuring a thickness and thickness deviation of resist layers prepared using the resist compositions of Experimental Examples 1 and 2, depending on a spin coating speed of the resist layer. Here, in Experimental Example 1, dimethylformamide was used as a solvent, and in Experimental Example 2, chloroform was used as a solvent.

TABLE 4

| Resist | spin coating | resist layer | thickness |
|---|---|---|---|
| composition | speed | thickness | variation |
| Experimental | 1000 rpm | 23 nm | 1 nm |
| Example 1 | 1500 rpm | 20 nm | 1 nm |
| Experimental | 1000 rpm | 22 nm | 1 nm |
| Example 2 | 1500 rpm | 16 nm | 1 nm |

Referring to Table 4, the resist layers prepared using the resist composition of Experimental Examples 1 and 2 may have a thin thickness and a small thickness deviation.

Table 5 shows the results of evaluating solubility of resist compounds and coating uniformity of resist layers depending on a type of solvent. Here, the resist compound of Experimental Example 1 and the resist compound of Experimental Example 2 were used for evaluation.

TABLE 5

| Resist | | | Uniformity of |
|---|---|---|---|
| compound | Solvent type | Solubility | resist layer |
| Experimental | Chloroform | ◯ | ◯ |
| Example 1 | Mixed solvent of chloroform | ◯ | ◯ |
| | and anisole | | |
| | Dimethylformamide | ◯ | ◯ |
| Experimental | Chloroform | ◯ | ◯ |
| Example 2 | | | |

Solubility evaluation
◯: good
X: poor
Uniformity of resist layer
◯: uniform
X: non-uniform

Referring to Table 5, the resist compound of Experimental Example 1 had high solubility in chloroform solvent, the mixed solvent of chloroform and anisole, and dimethylformamide solvent. When the resist composition including the resist compound of Experimental Example 1 was used, the resist layer was uniformly formed.

The resist compound of Experimental Example 2 had high solubility in chloroform solvent. When the resist composition including the resist compound of Experimental Example 2 was used, the resist layer was uniformly formed.

Table 6 shows whether a resist compound is prepared depending on the type of metal and results of evaluating characteristics of a resist layer prepared by using the resist compound. Whether the resist compound is prepared was evaluated by whether metal-O-dialkyl dithiocarbonate is prepared. In Table 6, a poor resist layer may include that the resist layer cannot be formed because the resist layer material is not prepared. The poor resist layer may include that the resist layer is not uniformly formed.

TABLE 6

| | Whether resist compound | Whether resist layer |
|---|---|---|
| Type of metal | is prepared or not | is good or poor |
| Indium | ◯ | X |
| Copper | X | X |
| Nickel | ◯ | X |
| Bismuth | X | X |
| Silver (Ag) | ◯ | ◯ |
| Tin (Sn) | ◯ | X |
| Antimony | X | X |

Whether resist compound is prepared or not
◯: prepared
X: not prepared or prepared material in a poor state (e.g., excessively high viscosity)
Whether resist layer is good or poor
◯: good
X: poor

Referring to Table 6, it may be confirmed that silver reacts with alkyl dithiocarbonate to prepare a resist compound. In addition, the resist compound containing silver (Ag) was evaluated as being good for forming a resist layer. For example, a resist compound including silver (Ag) may form a uniform resist layer.

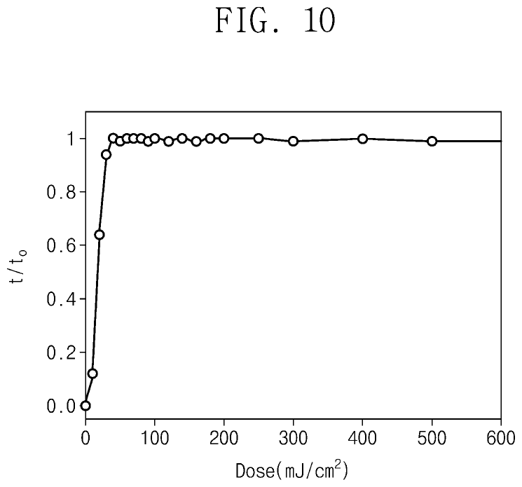

FIG. 10 shows the results of evaluating photosensitivity characteristics of a resist layer of Experimental Example 2 to EUV. The x-axis shows a dose amount, and the y-axis shows a result of measuring a thickness “t” measured depending on the dose amount of the resist layer with respect to an initial thickness “to” of an initial resist layer.

Table 7 shows the results of evaluating photosensitivity characteristics of the resist layers of Experimental Examples 1 and 2 with respect to EUV. The photosensitivity is evaluated by the dose when the measured thickness of the resist layer is 50% of the initial thickness of the resist laver.

TABLE 7

| | photosensitivity | |
|---|---|---|
| Experimental Example 1 | 16.8 | mJ/cm² |
| Experimental Example 2 | 300-400 | mJ/cm² |

Referring to FIGS. 10 and Table 7, the resist layers of Experimental Examples 1 and 2 show photosensitivity to EUV. The resist layer of Experimental Example 1 had sensitive photosensitivity to EUV.

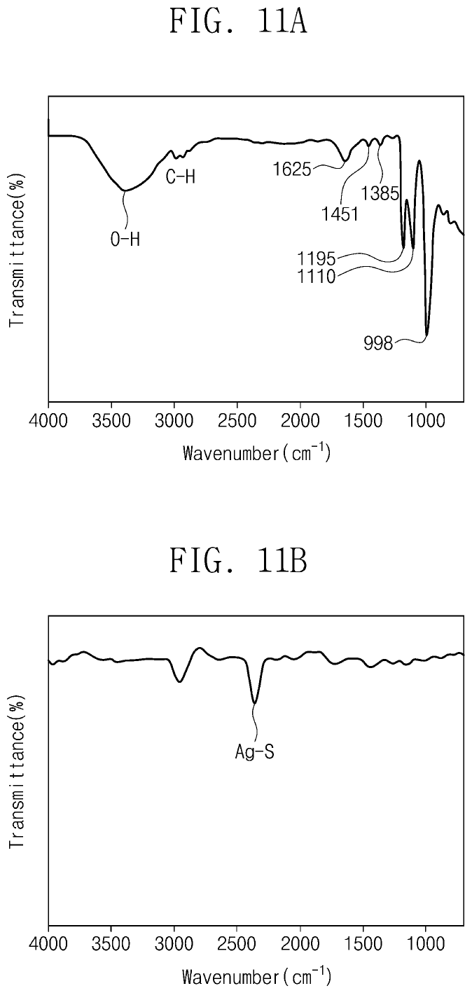

FIG. 11A shows the result of a Fourier-transform infrared spectroscopy (FT-IR) analysis of a resist layer of Experimental Example 1 before an exposure process. FIG. 11B shows the result of a Fourier transform infrared spectroscopic analysis of an exposed resist layer of Experimental Example 1 after an EUV exposure process.

Table 8 shows a chemical bond corresponding to a peak wavelength in a Fourier transform infrared spectrometer.

TABLE 8

| Wavenumber(cm−1) | Corresponding chemical bond |
|---|---|
| 1625 | C—H |
| 1451 | —CH₃(asymmetric) |
| 1385 | —CH₃(symmetric) |
| 1195 | C—O—C |
| 1110 | C—O |
| 998 | C═S |

Referring to FIGS. 11A and 11B, and Table 8, it was observed that a peak of an exposed resist layer of Experimental Example 1 was different from a peak of a resist layer before an exposure process. Therefore, it may be seen that when the resist layer is exposed to extreme ultraviolet (EUV), the chemical structure of a material included in the resist layer is changed. As a result of FT-IR analysis, the resist layer after the exposure process shows a peak corresponding to Ag—S bonding.

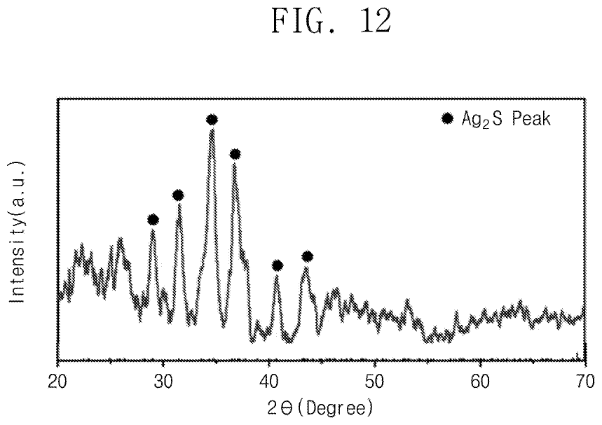

FIG. 12 shows the result of an X-ray diffraction (hereinafter, XRD) analysis of an EUV-exposed resist layer of Experimental Example 1.

Referring to FIG. 12, as a result of XRD analysis, the resist layer after the exposure process shows a peak corresponding to Ag₂S.

According to embodiments, the resist compound may react with light to change the chemical structure of the resist compound. The reaction of the resist compound by irradiation with EUV may be represented by Reaction Formula 1. For example, C₂H₄, carbonyl sulfide, and Ag₂S may be produced by the reaction of the resist compound.

According to the embodiment, the resist composition may have the high absorbance and high reactivity to electron beams and/or extreme ultraviolet. Accordingly, the resist layer prepared using the resist composition may be well patterned.

While example embodiments have been particularly shown and described, it will be understood by one of ordinary skill in the art that variations in form and detail may be made therein without departing from the spirit and scope of the attached claims.

What is claimed is:

1. A resist compound represented by Formula 1: 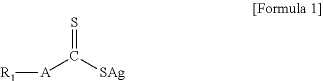
wherein R₁ is an alkyl group having 1 to 12 carbon atoms, an alkenyl group having 1 to 12 carbon atoms, or a hydrocarbon ring group having 3 to 12 carbon atoms, and A bonded to R₁ is O or NR₂, wherein R₂ is hydrogen, an alkyl group having 1 to 12 carbon atoms, an alkenyl group having 1 to 12 carbon atoms, or a hydrocarbon ring group having 3 to 12 carbon atoms.

2. The resist compound of claim 1, wherein the resist compound is represented by Formula 2: 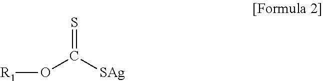
wherein R₁ is an alkyl group having 1 to 12 carbon atoms, an alkenyl group having 1 to 12 carbon atoms, or a hydrocarbon ring group having 3 to 12 carbon atoms.

3. The resist compound of claim 1, wherein the resist compound is represented by Formula 3: 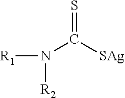
wherein R₁ is an alkyl group having 1 to 12 carbon atoms, an alkenyl group having 1 to 12 carbon atoms, or a hydrocarbon ring group having 3 to 12 carbon atoms, and R₂ is hydrogen, an alkyl group having 1 to 12 carbon atoms, an alkenyl group having 1 to 12 carbon atoms, or a hydrocarbon ring group having 3 to 12 carbon atoms.

4. The resist compound of claim 3, wherein, in Formula 3, R₂ is hydrogen.

5. The resist compound of claim 1, wherein the material represented by Formula 1 has reactivity to extreme ultraviolet.

6. The resist compound of claim 1, wherein, in Formula 1, R₁ is an ethyl group, a propyl group, a butyl group, or a pentyl group.

7. The resist compound of claim 1, wherein, in Formula 1, R₁ is an ethyl group, and A bonded to R₁ is O.

8. A resist composition comprising
a resist compound represented by Formula 1; and
an organic solvent; 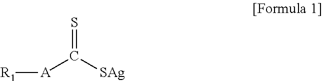
wherein R₁ is an alkyl group having 1 to 12 carbon atoms, an alkenyl group having 1 to 12 carbon atoms, or a hydrocarbon ring group having 3 to 12 carbon atoms, and A bonded to R₁ is O or NR₂, wherein R₂ is hydrogen, an alkyl group having 1 to 12 carbon atoms, an alkenyl group having 1 to 12 carbon atoms, or a hydrocarbon ring group having 3 to 12 carbon atoms.

9. The resist composition of claim 8, wherein, in Formula 1, A bonded to R₁ is O.

10. The resist composition of claim 9, wherein, in Formula 1, R₁ is an ethyl group.

11. The resist composition of claim 9, wherein, in Formula 1, R₁ is a propyl group.

12. The resist composition of claim 8,
wherein the compound represented by Formula 1 is a compound represented by Formula 3: 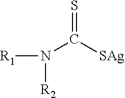
wherein R₁ is an alkyl group having 1 to 12 carbon atoms, an alkenyl group having 1 to 12 carbon atoms, or a hydrocarbon ring group having 3 to 12 carbon atoms, and R₂ is hydrogen, an alkyl group having 1 to 12 carbon atoms, an alkenyl group having 1 to 12 carbon atoms, or a hydrocarbon ring group having 3 to 12 carbon atoms.

13. The resist composition of claim 8, wherein, in Formula 1, R₁ is an alkyl group having 1 to 5 carbon atoms.

14. The resist composition of claim 8, wherein the resist compound has reactivity to extreme ultraviolet or electromagnetic radiation.

15. The resist composition of claim 8, wherein the organic solvent includes an alcohol solvent, a nitrile solvent, an acetate solvent, a halogenated alkyl solvent, an aromatic ether solvent, and/or an amide solvent.

16. A method of forming a resist pattern comprising:
forming a resist layer by applying a resist composition including the resist compound according to claim 1 on a substrate;
performing an exposure process of irradiating light onto the resist layer to provide an irradiated resist layer; and
performing a developing process on the irradiated resist layer to form a resist pattern.

17. The method of forming the resist pattern of claim 16, wherein the light is extreme ultraviolet.

18. The method of forming the resist pattern of claim 17, wherein the resist layer formed by applying the resist composition comprises a first portion and a second portion, and the method further comprises forming a mask pattern on the second portion of the resist layer, wherein the performing of the exposure process includes irradiating the light onto the first portion of the resist layer to change a chemical structure of the resist compound included in the first portion of the resist layer.

19. The method of forming the resist pattern of claim 18, wherein the forming of the resist pattern includes removing the first portion of the resist layer using a developer solution in the performing of the developing process.

20. The method of forming the resist pattern of claim 17, wherein the resist composition further includes an organic solvent, and
wherein the organic solvent includes an alcohol solvent, a nitrile solvent, an acetate solvent, a halogenated alkyl solvent, an aromatic ether solvent, and/or an amide solvent.
